(19) United States
(12) Patent Application Publication
(10) Pub. No.: US 2013/0182462 A1
(43) Pub. Date: Jul. 18, 2013

(54) LINEAR SYNCHRONOUS RECTIFIER DRIVE CIRCUIT

(71) Applicant: Jeff Sorge, Westminster, CO (US)

(72) Inventor: Jeff Sorge, Westminster, CO (US)

(73) Assignee: Murata Manufacturing Co., Ltd., Nagaokakyo-shi (JP)

(21) Appl. No.: 13/349,765

(22) Filed: Jan. 13, 2012

(51) Int. Cl. H02M 3/335; H03B 1/00

(52) U.S. Cl. 363/21.02; 327/109

(57) ABSTRACT

A drive circuit arranged to drive a synchronous rectifier of a power converter includes a differential amplifier stage connected to the synchronous rectifier and arranged to supply a drive signal to the synchronous rectifier to turn the synchronous rectifier on and off and a high voltage blocking stage connected between the synchronous rectifier and the differential amplifier stage. The differential amplifier stage is arranged such that a voltage level of the drive signal depends on a load of the power converter.

### BACKGROUND OF THE INVENTION

1. Field of the Invention

The present invention relates to a drive circuit for a synchronous rectifier of a power converter, and more specifically, to a self-contained linear drive circuit for a synchronous rectifier of a power converter that requires no connection to the power converter control circuit.

2. Description of the Related Art

Various conventional techniques have been used to control synchronous rectifiers, including direct connection to the power supply control circuit, transformer coupling to the power supply control circuit, self-driven techniques using windings of the main transformer, and linear amplifier techniques.

For example, Berghegger (US 2010/0123486) shows a known linear amplifier technique used to control a synchronous rectifier. FIG. 1 of the present application is a copy of FIG. 2 from Berghegger. In FIG. 1 of the present application, the primary side of the power converter includes a primary winding Np of transformer T1 that is connected to a first power switch S₁ with gate drive terminal GD₁ and to an input voltage Vᵢₙ. A first resistor R1 is connected to the input voltage Vᵢₙ and the primary winding Np. The secondary side of the power converter includes a load represented by a battery with an output voltage Vₒᵤₜ and second and third resistors R2, R3. The secondary side also include a synchronous rectifier switch SR, shown as an n-channel metal oxide semiconductor field-effect transistor (MOSFET) with source “s”, drain “d”, and gate “g”, which is connected to a driver circuit that includes the first, second and third driver switches Q1, Q2, Q3, the first diode D1, and fourth, fifth and sixth resistors R4, R5, R6. The first and second driver switches Q1, Q2 define at least a portion of a differential amplifier. The collector voltage of the first driver switch Q1 controls the voltage of a drive signal SRGD to the synchronous rectifier switch SR. The switch-on current is amplified by a third driver switch Q3, coupled between a collector terminal of the first driver switch Q1 and the gate of the synchronous rectifier switch SR, to reduce the switch-on time of the synchronous rectifier switch SR.

The circuit shown in FIG. 1 uses bipolar transistors for the differential amplifier stage. To provide the high voltage blocking capability of the differential amplifier stage when the synchronous rectifier switch SR is off, the circuit shown in FIG. 1 reverses the collector and emitter connections of the second driver switch Q2 connected to the drain of the synchronous rectifier switch SR. This reverse connection increases the rated reverse voltage of the emitter-to-base connection from a few volts (typically 6 V) to the collector-to-base connection which can be 10 s to 100 s of volts. The reverse connection is referred to as operating the transistor in the inverted mode. While operating a transistor in the inverted mode greatly increases the reverse breakdown voltage of the input terminals by using the base-to-collector connection instead of the base-to-emitter connection, it also results in a very low gain transistor as discussed in paragraph [0023] of Berghegger. A very low gain transistor is not necessarily a problem if high gain is not required for the second driver switch Q2. In fact, Berghegger proposes shorting out the emitter e and base b terminals of second driver switch Q2 in FIG. 4 of Berghegger (not included in the drawings with this specification), or completely replacing the second driver switch Q2 with a matched diode as shown in FIG. 10 of Berghegger (not included in the drawings with this specification).

The main problem with the Berghegger circuit is the speed with which the first driver switch Q1 can be turned off. The turn on of the synchronous rectifier switch SR coincides with the turn off of the first driver switch Q1. The additional turn off delay of the first driver switch Q1 due to the bipolar transistor storage time results in coincident delay to the turn on of the synchronous rectifier switch SR. Bipolar transistors have a relatively long storage time associated with the stored charge in the base region after the bipolar transistor has been in saturation. It takes time to sweep the charge from the bipolar transistor base before the collector current can stop flowing. This time can be reduced by driving the base harder, which is to say shorting the base to the emitter with a low impedance, or even applying a negative voltage to the base-emitter to speed the process of sweeping out the charge, as used in a Baker clamp. Because the first and second driver switches Q1 and Q2 form a simple differential amplifier, there is no way to provide a more substantial drive to the base of the first driver switch Q1. This delay in sweeping the charge from the bipolar transistor base limits the useful maximum operating frequency of the Berghegger circuit, as there will be a significant delay (e.g., 100 s of nanoseconds) to turn on the gate drive of the synchronous rectifier switch SR. This results in an extended period of time in which the load current flows through the body diode of the synchronous rectifier switch SR at the beginning of the conduction interval before the gate-to-source voltage is high enough to enhance the drain-to-source channel of the synchronous rectifier switch SR. Body diode conduction is similar to standard diode rectification and results in a much higher voltage drop from source to drain of the synchronous rectifier switch SR. As a result, the improvements in efficiency afforded by synchronous rectification are significantly diminished at high frequencies.

### SUMMARY OF THE INVENTION

To overcome the problems described above, preferred embodiments of the present invention provide a drive circuit for a synchronous rectifier that is linear, that is self contained, and that requires no connections to the power converter control circuit, where the power converter control circuit regulates the output voltage by controlling the timing of the primary power switches.

In the preferred embodiments of the present invention, the differential amplifier stage is not limited to bipolar transistors and can use either bipolar transistors or MOSFETs. Further, the high breakdown voltage of the differential amplifier stage of the preferred embodiments of the present invention is preferably provided by an additional MOSFET switch, instead of using the inverted mode. The differential amplifier stages of the preferred embodiments of the present invention can be precisely matched with the two differential transistors connected in the same configuration. The high voltage blocking switch can block any off state voltage on the drain of the synchronous rectifiers up to the drain-to-source breakdown rating of the high voltage blocking switch, which is preferably a MOSFET. In this manner, the differential amplifier stage can preferably include a low voltage, high transconductance, and high speed devices, while the high voltage protection can be preferably provided by a separate high speed, high voltage blocking switch.

Preferred embodiments of the present invention do not require additional drive transformers or windings for operation. In preferred embodiments of the present invention, a linear drive mechanism automatically reduces the gate drive voltage level as the load of the power converter is reduced, which reduces drive power losses when there is little to gain from additional enhancement of the synchronous rectifier. In preferred embodiments of the present invention, the use of synchronous rectifiers improves the efficiency of the power converter by reducing the forward voltage drop of the rectifier in accordance with the gain curve of the drive circuit.

According to a preferred embodiment of the present invention, a drive circuit arranged to drive a synchronous rectifier of a power converter includes a differential amplifier stage connected to the synchronous rectifier and arranged to supply a drive signal to the synchronous rectifier to turn the synchronous rectifier on and off and a high voltage blocking stage connected between the synchronous rectifier and the differential amplifier stage. The differential amplifier stage is arranged such that a voltage level of the drive signal depends on a load of the power converter.

The differential amplifier stage preferably includes first and second transistors. The first transistor is preferably arranged to be connected to the synchronous rectifier to supply the drive signal, and the second transistor is preferably arranged to receive a signal corresponding to the load of the power converter. The first and second transistors are preferably arranged such that the voltage level of the drive signal depends on a transconductance of the first transistor and a drain-to-source voltage of the synchronous rectifier. The drive circuit preferably includes a first resistor connected to the first transistor and a second resistor connected to the second transistor. The voltage level of the drive signal preferably depends on a resistance of the first resistor. The resistance of the first resistor is preferably the same as a resistance of the second resistor. The first and second transistors are preferably included in a single package.

The drive circuit preferably includes a buffer circuit connected between the differential amplifier stage and the synchronous rectifier. The voltage level of the drive signal is preferably automatically reduced when the load is reduced.

The differential amplifier stage is preferably a linear differential amplifier stage. The synchronous rectifier is preferably a MOSFET. The first and second transistors are preferably MOSFETs or bipolar transistors.

The driver circuit preferably includes a current mirror arranged to increase a gain of the drive circuit.

According to a preferred embodiment of the present invention, a power converter includes a transformer including primary and secondary windings, a synchronous rectifier connected to the secondary winding, and a drive circuit according to another preferred embodiment of the present invention connected to the synchronous rectifier to drive the synchronous rectifier.

The power converter preferably includes a primary switch connected to the primary winding and a control circuit connected to the primary switch. The drive circuit is preferably not connected to the control circuit. The power converter preferably includes an output filter stage. The power converter preferably is a critical conduction mode flyback power converter. The control circuit is preferably arranged to provide zero voltage switching of the primary switch.

According to a preferred embodiment of the present invention, a power converter includes first and second synchronous rectifiers, first and second drive circuits according to another preferred embodiment of the present invention connected to the first and second synchronous rectifiers, respectively, to drive the first and second synchronous rectifiers.

The power converter preferably includes a transformer including primary and secondary windings. The first and second synchronous rectifiers are preferably connected to the secondary winding.

Accordingly to a preferred embodiment of the present invention, a power converter system preferably includes first and second power supplies connected to provide a single output. Each of the first and second power supplies preferably includes an ORing transistor preferably arranged to act as a diode and a drive circuit preferably arranged to drive the ORing transistor including a differential amplifier stage connected to the ORing transistor and arranged to supply a drive signal to the ORing transistor to turn the ORing transistor on and off. The differential amplifier stage is preferably arranged such that a voltage level of the drive signal depends on a load of a corresponding one of the first and second power supplies.

The above and other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 shows a conventional drive circuit for a linear synchronous rectifier circuit.

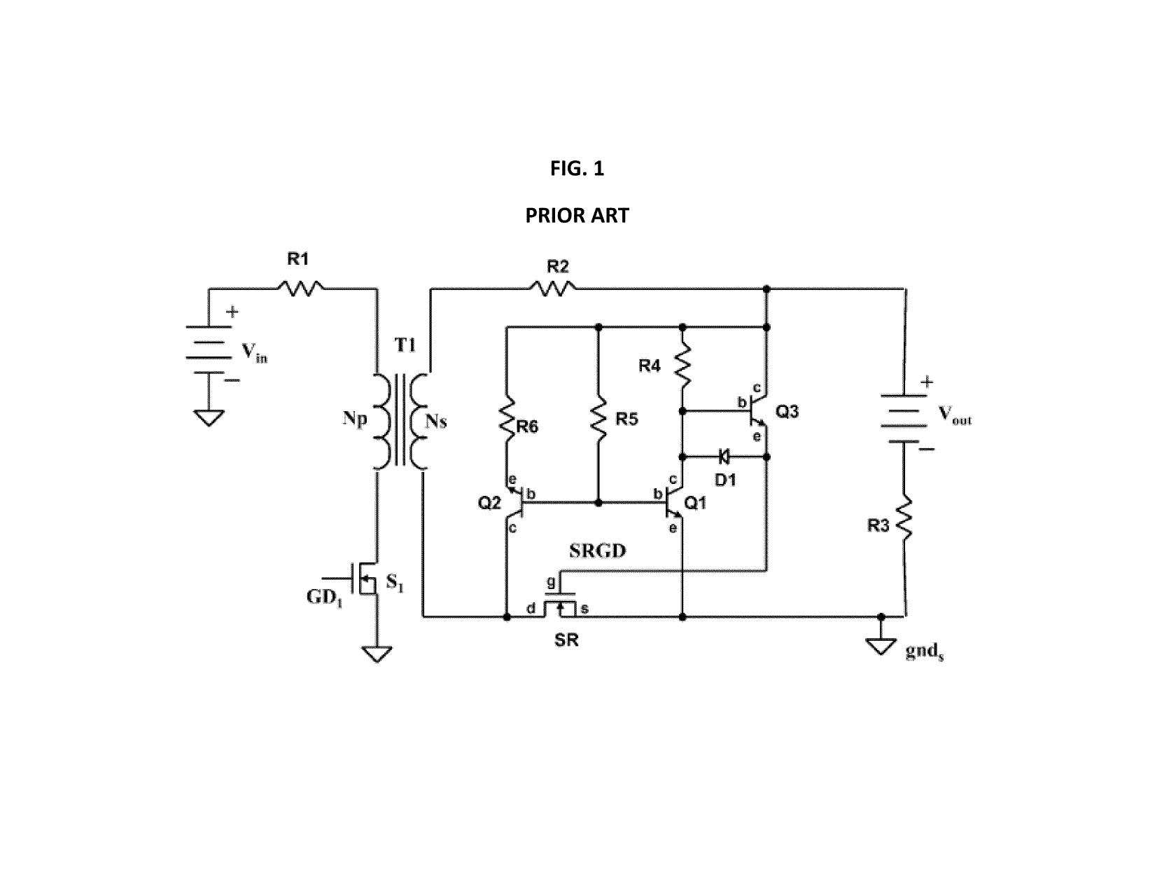

FIG. 2 is a graph showing that the gain of the differential amplifier stage is based on the transconductance of the differential transistor pair.

FIG. 3 is a graph showing that the synchronous rectifier has gain in the form of an on resistance that is a function of the gate-to-source voltage.

FIG. 4 is a graph showing that the synchronous rectifier gate-to-source voltage to on resistance gain can be translated into a voltage gain by including the operating current in the drain.

FIG. 5 is a graph showing that the intersection of the differential amplifier stage gain curve and the synchronous rectifier gate-to-source voltage to drain-to-source resistance characteristic establishes the operating points of the drive circuit according to preferred embodiments of the present invention.

FIG. 6 is a circuit diagram of a power converter including a drive circuit according to a first preferred embodiment of the present invention.

FIG. 7 is a circuit diagram of the drive circuit shown in FIG. 6.

FIG. 8 is a circuit diagram of a power converter including a drive circuit according to a second preferred embodiment of the present invention.

FIG. 9 is a circuit diagram of a power converter including power supplies and drive circuits connected in parallel according to a third preferred embodiment of the present invention.

FIG. 10 is a circuit diagram of a power converter including a drive circuit according to a fourth preferred embodiment of the present invention.

### DETAILED DESCRIPTION OF PREFERRED EMBODIMENTS

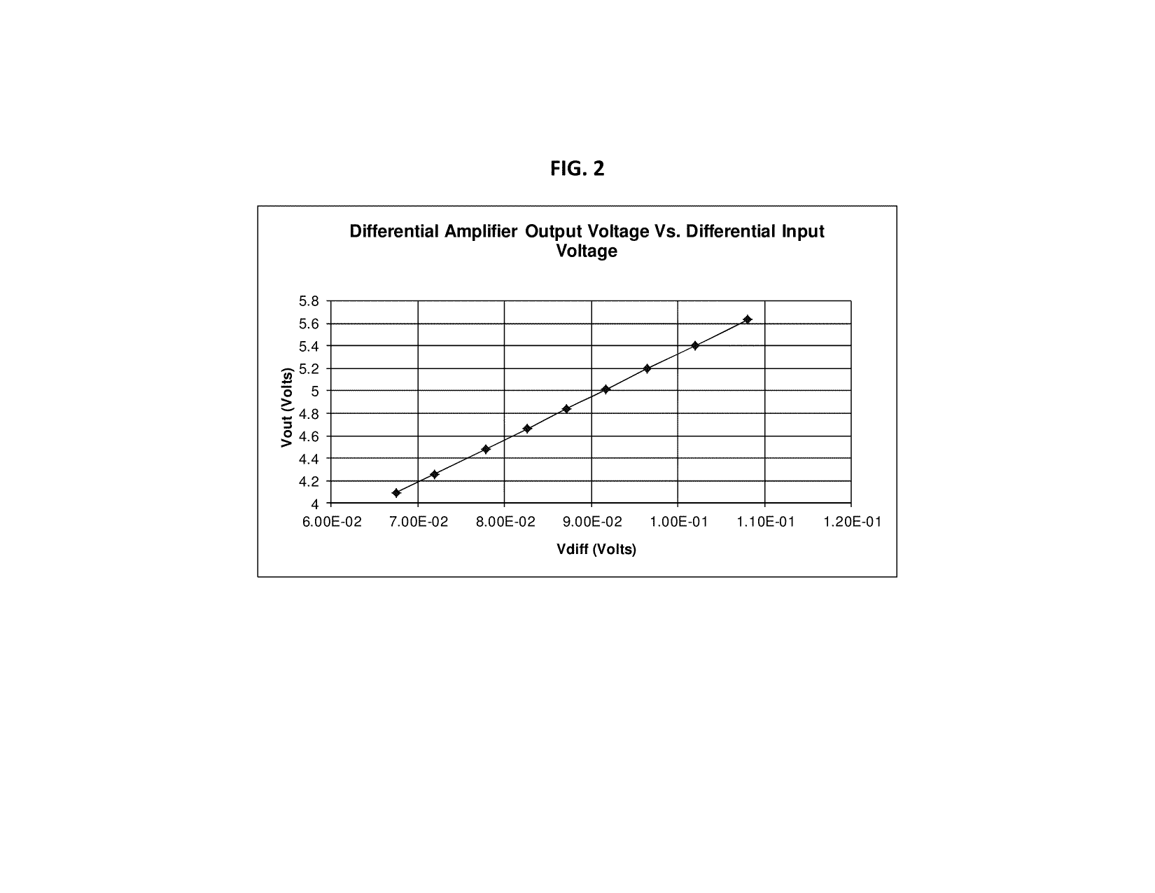

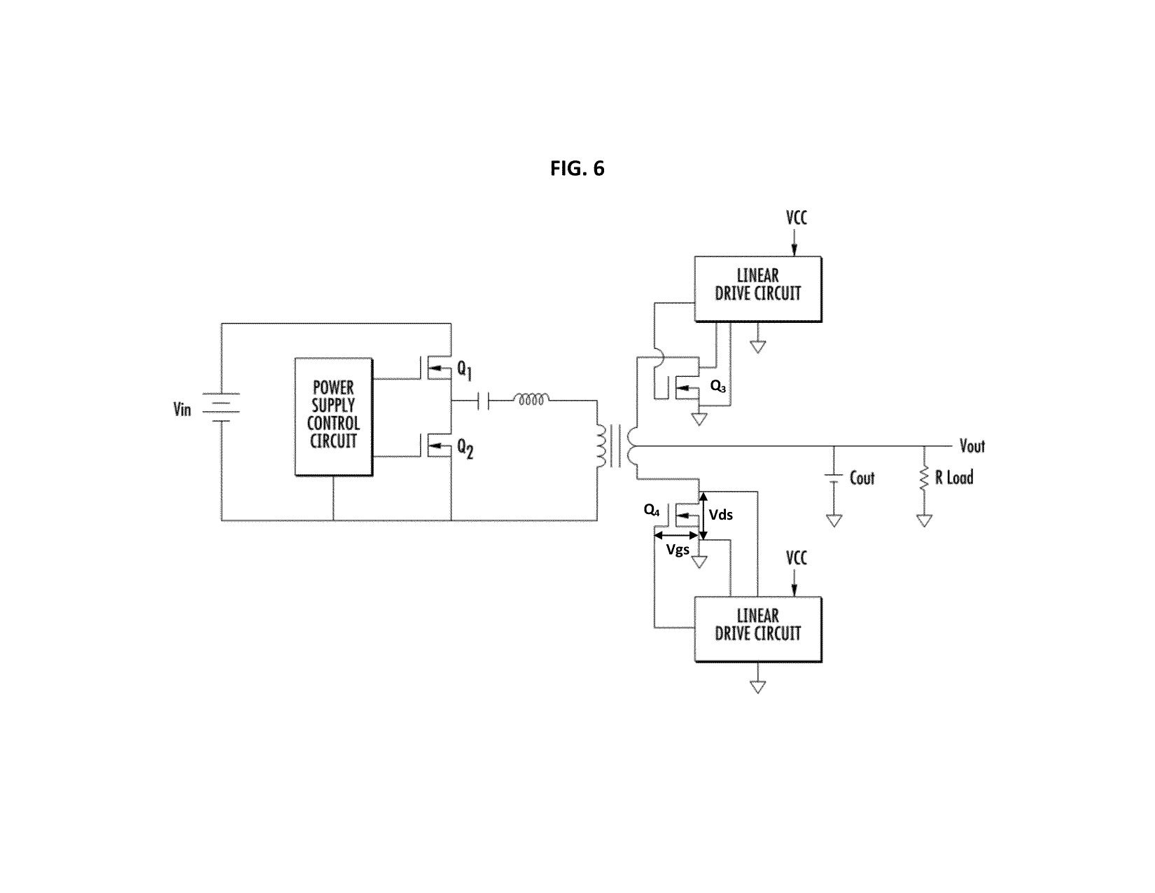

Preferred embodiments of the present invention are described with reference to FIGS. 2-10. FIGS. 2-5 show graphs explaining various aspects of preferred embodiments of the present invention. FIGS. 6-10 show power converter circuits including drive circuits according to various preferred embodiments of the present invention.

In various preferred embodiments of the present invention, a drive circuit is linear, is self-contained, and controls the drain-to-source voltage drop of the synchronous rectifier to be less than that of a forward diode voltage drop with no additional transformers or windings. Power loss of the drive circuit shown in FIG. 6 from driving the gate of the synchronous rectifier is equal to Ciss×Vcc×Vgs×fs, where Ciss is the gate capacitance of the synchronous rectifier Q4 when the drain-to-source voltage Vds is zero, Vcc is the supply voltage for the drive circuit, Vgs is the gate-to-source voltage that is actually applied to the synchronous rectifier Q4 gate when the synchronous rectifier Q4 is conducting, and fs is the switching frequency of the synchronous rectifier Q4. This power loss can be reduced at light loads when a higher drain-to-source resistance Rds can be tolerated by reducing the voltage level of the voltage applied to the gate (or drive) terminal Vgs.

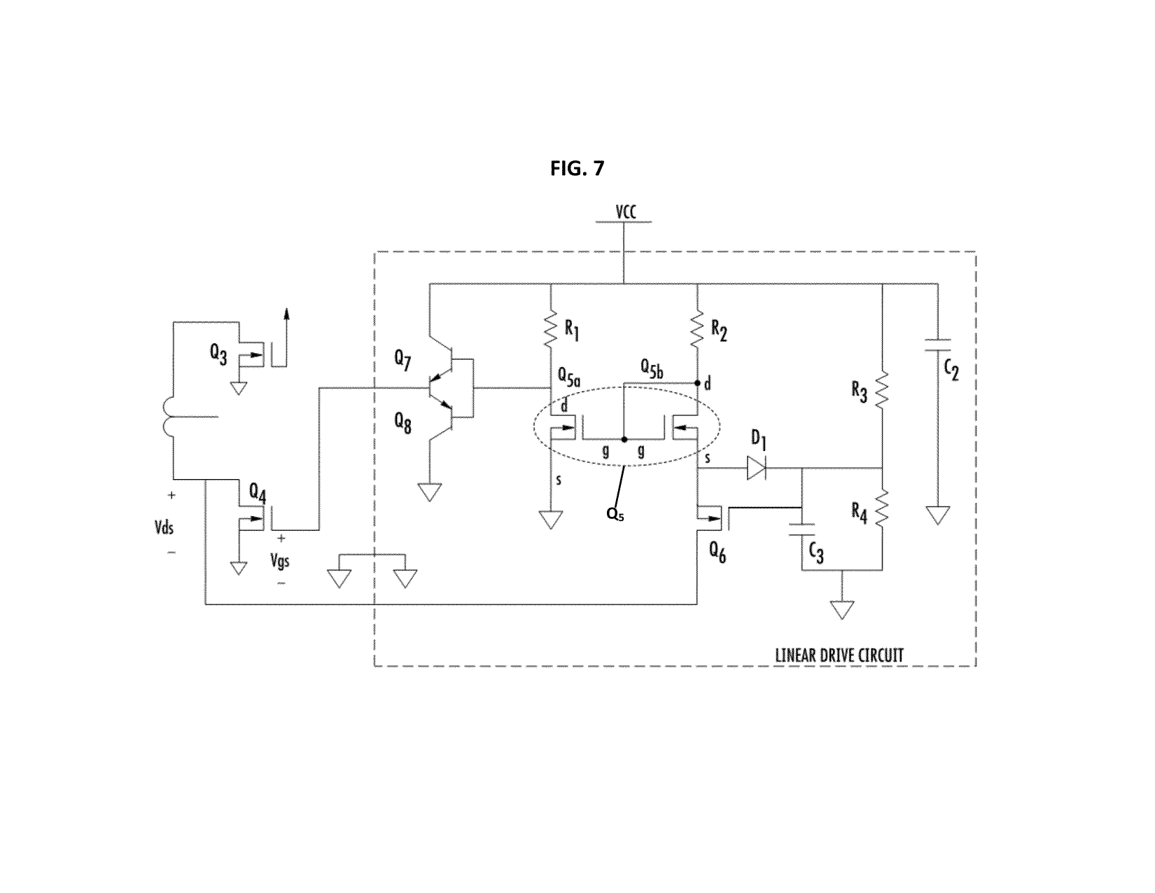

The drive circuit of the preferred embodiments of the present invention preferably does this automatically based on the transconductance of the linear differential amplifier stage and the transconductance of the synchronous rectifier. It is possible to use a comparator, instead of a differential amplifier, to sense the output current of the power supply, and at a discrete point (or points), to lower the drive voltage applied to the data terminal. This is explained in more detail as follows. Referring to FIG. 7 below, the differential transistor pair Q5a and Q5b define a differential amplifier stage. Because the source of the differential transistor Q5a is connected directly to ground, the differential input is equal to the drain-to-source voltage Vds of the synchronous rectifier Q4. The small signal gain of the differential amplifier stage from drain-to-source voltage Vds to the synchronous rectifier Q4 gate is thus −gfs×Res1 where gfs is the forward transconductance of differential transistor Q5a at the operating point established by differential transistor Q5b and resistor R2, and Res1 is the resistance of resistor R1. A typical gain curve for the differential amplifier stage is shown in FIG. 2, which is a graph that shows that the gain of the differential amplifier stage is based on the transconductances of each of the differential transistors Q5a and Q5b. The operating transconductance of the differential transistor pair is a function of the operating point drain current when the drain-to-source voltage Vds is zero. Therefore, differential transistor Q5b sets the operating point transconductance for both differential transistors Q5a and Q5b with the current through resistor R2, and the differential transistor Q5a converts the drain current into voltage through resistor R1.

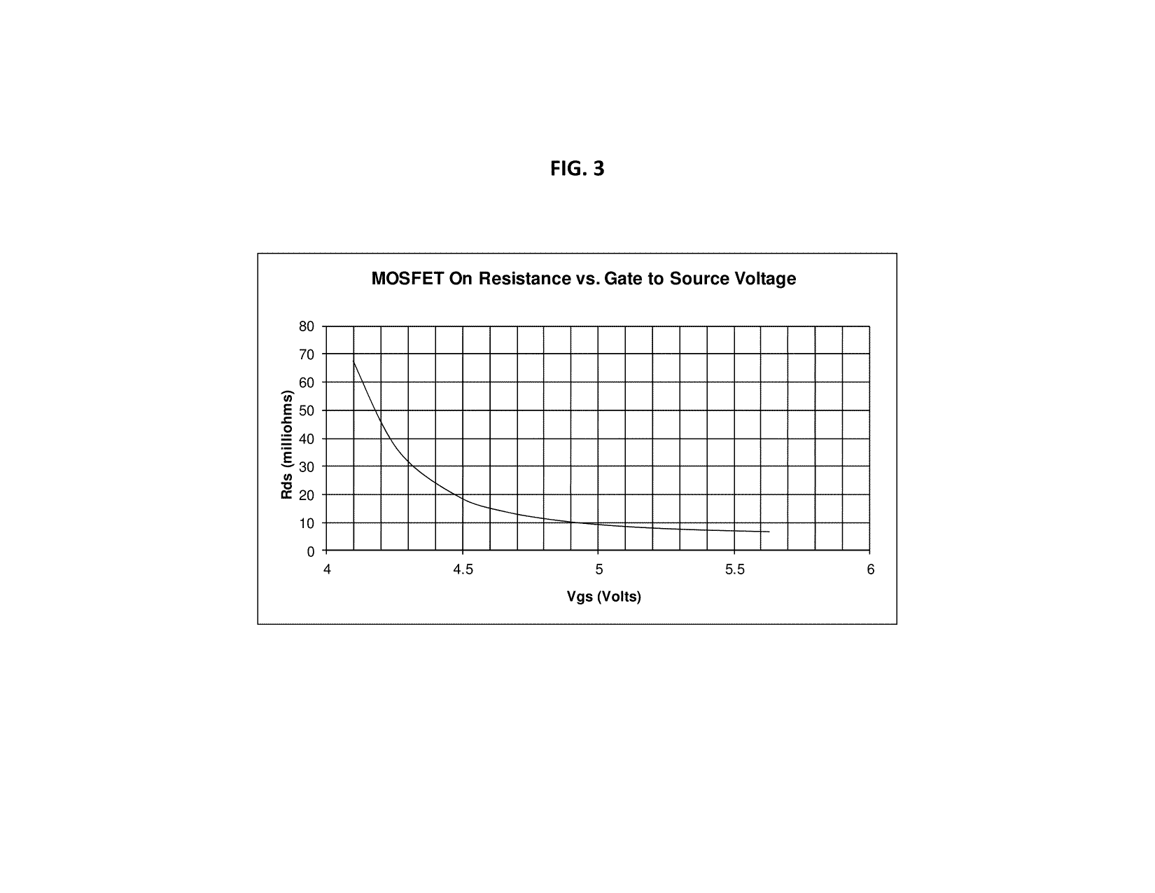

In addition to the gain of the differential amplifier stage, the synchronous rectifier also has gain in the ohmic region. Increasing the gate-to-source voltage Vgs of the synchronous rectifier reduces the drain-to-source resistance Rds as shown in FIG. 3. FIG. 3 is a graph showing that the synchronous rectifier also has gain in the form of an on resistance RdsOn as a function of the gate-to-source voltage Vgs.

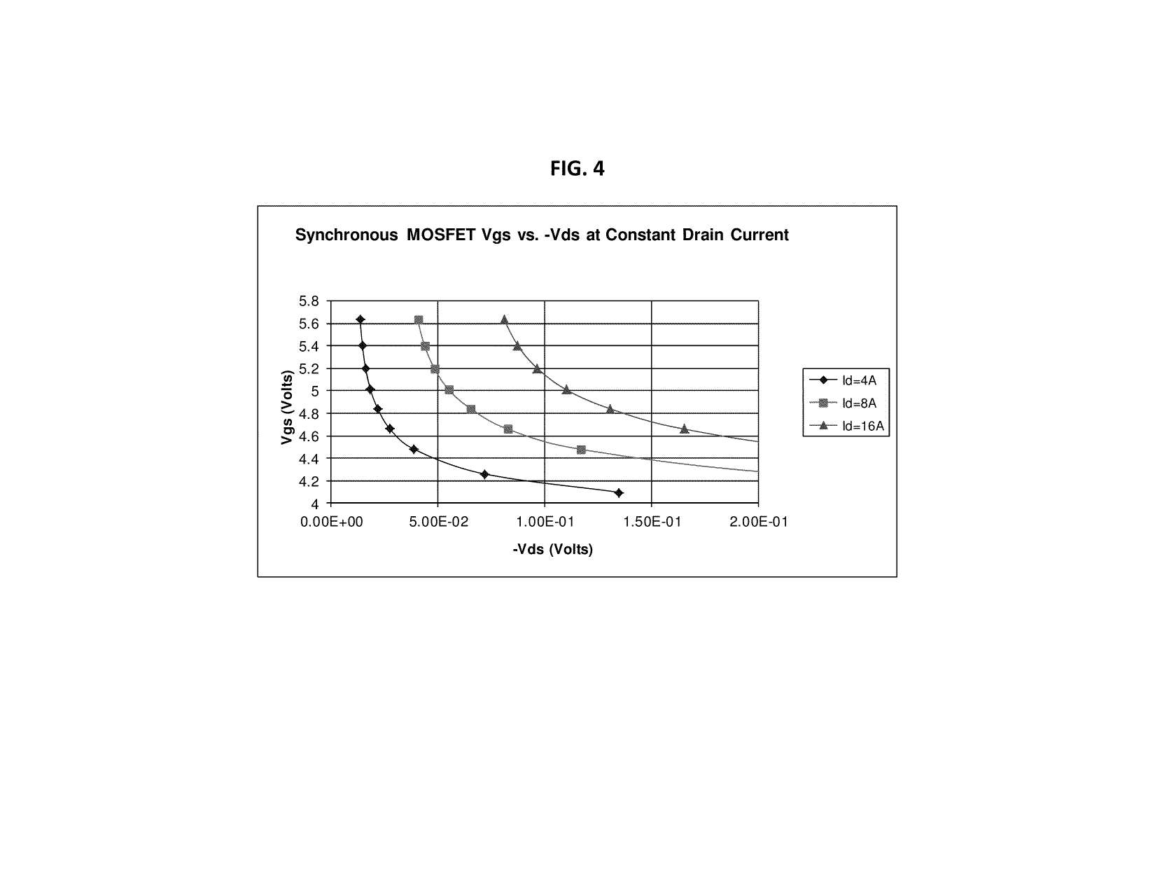

When operating, the drain-to-source current of the synchronous rectifier is also considered. The synchronous rectifier exhibits a relationship between the gate-to-source voltage Vgs and the drain-to-source voltage Vds for a given level of the drain current as shown in FIG. 4. FIG. 4 is a graph showing that the synchronous rectifier gate-to-source voltage Vgs to on resistance RdsOn gain can be translated to a voltage gain by including the operating current in the drain.

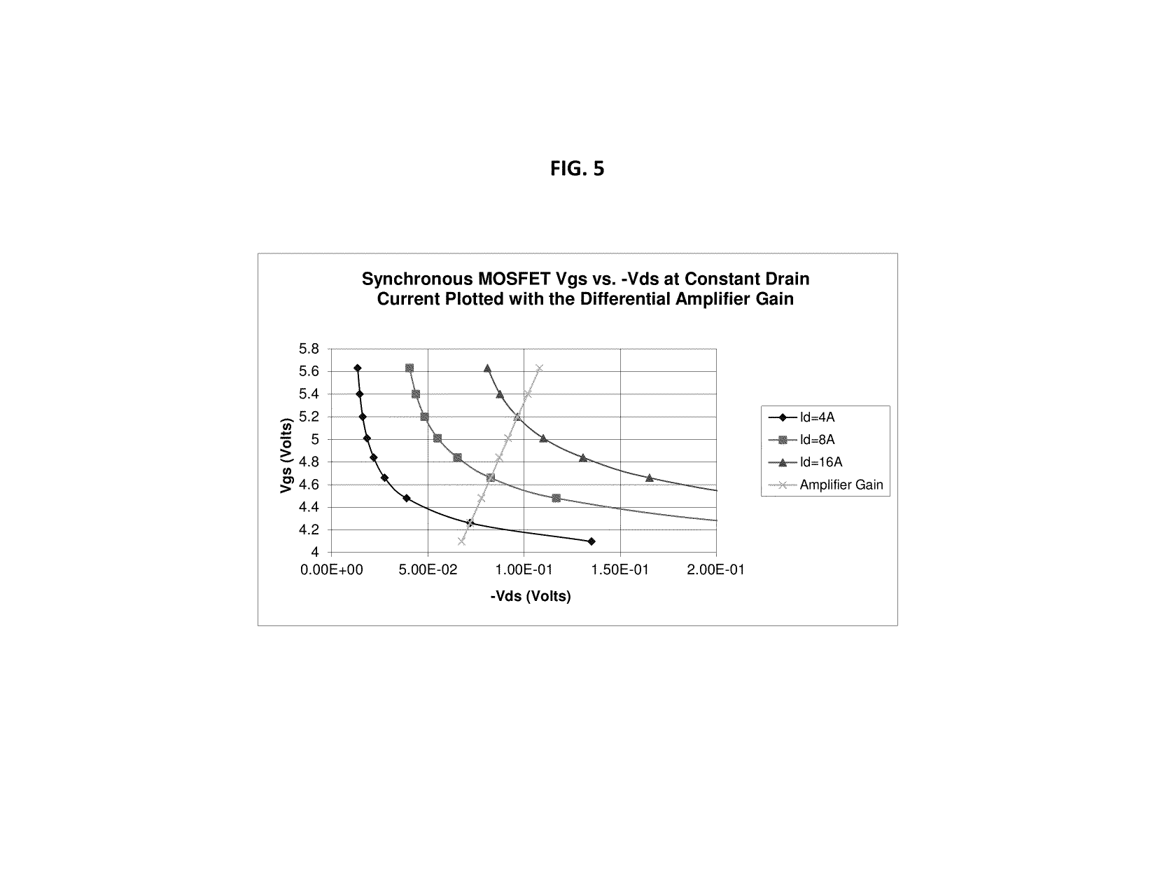

The characteristics of the differential amplifier stage and the synchronous rectifier can be plotted together as shown in FIG. 5 to show the operating voltage of the gate-to-source voltage Vgs for various drain current levels. Because the differential amplifier stage output voltage is essentially the same as the gate-to-source voltage Vgs of the synchronous rectifier, the points where the curves intersect are the operating points of the drive circuit. Therefore, the drive voltage level to the synchronous rectifier (i.e., the gate-to-source voltage Vgs) is a function of the load current resulting in reduced drive voltage levels at reduced load currents. FIG. 5 is a graph showing that the intersection of the differential amplifier stage gain curve and the synchronous rectifier gate-to-source voltage Vgs to drain-to-source voltage −Vds characteristic establishes the operating points of the drive circuit.

The percentage efficiency loss because of output rectification can be approximated as (−Vds)/Vout*100, where −Vds is the voltage drop across the rectifying device, which is either a synchronous rectifier or a diode, and Vout is the output voltage. Diode voltage drops in rectifier applications typically range from about 0.35 V to about 1.1 V, for example. The synchronous rectifier controlled by the drive circuit of the preferred embodiments of the present invention preferably will have a forward voltage drop of less than about 0.1 V, for example.

FIG. 6 is a circuit diagram showing a power converter including a drive circuit of the first preferred embodiment of the present invention in a typical application of an LLC resonant converter. The LLC resonant converter includes primary switches Q1 and Q2 which preferably turn on and off alternately with a 50% duty factor DF, for example. A power supply control circuit is used to regulate the output voltage Vout of the LLC converter by varying the switching frequency of the primary switches Q1 and Q2. On the secondary side of the transformer, synchronous rectifiers Q3 and Q4 provide full wave rectification of the transformer secondary voltage to produce a regulated DC output voltage. The drive circuit shown in FIG. 6 controls the synchronous rectifiers Q3 and Q4 to operate like rectifier diodes by enhancing the gate drives of the synchronous rectifiers Q3 and Q4 when current is flowing from source to drain and by removing the gate drives of the synchronous rectifiers Q3 and Q4 to turn off the synchronous rectifiers Q3 and Q4 when the current attempts to reverse direction to flow from drain to source. The output capacitor Cout filters the fluctuating current from the transformer secondary to provide a steady DC output voltage to the load Rload. It is possible to use another suitable filtering circuit in addition to or instead of output capacitor Cout. The synchronous rectifiers Q3 and Q4 are preferably MOSFETs, as shown in FIG. 6.

FIG. 7 is a detailed circuit diagram of the drive circuit according to the first preferred embodiment of the present invention. The drive circuit of FIG. 7 includes a matched differential transistor pair Q5a and Q5b and a high voltage blocking switch Q6.

FIG. 7 only shows a portion of the circuit of the power converter. The synchronous rectifier Q4 is driven through a buffer stage including transistors Q7 and Q8. The buffer stage provides current gain to the output of the differential amplifier stage Q5 so that the gate capacitance of the synchronous rectifiers Q3 and Q4 can be charged and discharged quickly. Without the buffer stage, the gate capacitances of the synchronous rectifiers Q3 and Q4 might overload the differential amplifier stage Q5 output, causing excessive delays to enhance or cut off the channels of the synchronous rectifiers Q3 and Q4. At turn on, there might be body diode conduction during the beginning of the cycle, causing additional voltage drop and power loss. At turn off, it might take longer to get the channels of the synchronous rectifiers Q3 and Q4 to turn off again, which would increase the switching loss of the synchronous rectifiers Q3 and Q4 and/or the primary switches Q1 and Q2. The differential transistor pair Q5a and Q5b senses the drain-to-source voltage Vds across the synchronous rectifier Q4. The differential transistor pair Q5a and Q5b is preferably contained in the same package (i.e., the differential amplifier stage Q5) to provide reasonable matching between the two transistors Q5a and Q5b. The biasing resistors R1 and R2 are matched or mismatched to control the gate voltage level when the detected voltage across the synchronous rectifier Q4 is zero.

When the two biasing resistors R1 and R2 are the same value, the drain voltages of the differential transistor pair Q5a and Q5b will be the same provided that the drain-to-source voltage Vds of the synchronous rectifier Q4 is zero. Because the gate and drain of the differential transistor Q5b are connected together, the drain voltage and the gate voltage will be equal to that gate voltage which is required to establish a drain current per the transconductance of the differential amplifier stage Q5 that will create a voltage drop across the resistor R2 that will result in a stable operating point for the differential transistor Q5b.

Similarly, because the gates of the differential transistor pair Q5a and Q5b are connected together and because the drain-to-source voltage Vds across the synchronous rectifier Q4 is assumed to be zero, the operating point for the differential transistor Q5a will be the same as for the differential transistor Q5b, and the drain voltage of the differential transistor Q5a will be approximately the same as its gate voltage. This circuit balance can be adjusted so that the drain voltage of the differential transistors Q5a is higher or lower when the drain-to-source voltage Vds of the synchronous rectifier Q4 is zero.

If, for example, the resistance of resistor R1 is made to be smaller than the resistance of resistor R2, then there will be less voltage drop across the resistor R1 because the drain currents of the differential transistor pair Q5a and Q5b will still be essentially the same because the gate-to-source voltages are still the same. This will result in a higher voltage at the drain of the differential transistor Q5a. On the other hand, if, for example, the resistance of resistor R1 is made to be larger than the resistance of resistor R2, then there will be more voltage drop across resistor R1, and the drain voltage of the differential transistor Q5a will be lower.

The transconductance of the differential amplifier stage Q5 sets the linear gain from the negative drain-to-source voltage Vds of the synchronous rectifier Q4 to the gate-to-source voltage Vgs of the synchronous rectifier Q4. Higher gain transistors can be used for the differential transistor pair Q5a and Q5b to achieve higher levels of synchronous rectifier Q4 gate drive voltage for a given synchronous rectifier Q4 drain-to-source Vds negative voltage drop. When synchronous rectifier Q4 is turned off, there will be a high voltage at the synchronous rectifier Q4 drain. Depending on the application, this voltage can exceed the gate-to-source rating of the differential amplifier stage Q5. To allow the drive circuit to be used at synchronous rectifier Q4 drain voltage levels greater than about 30 V, for example, the high voltage blocking switch Q6 is added to block the high voltage from the differential transistor Q5b source. The high voltage blocking switch Q6 is biased with a common gate configuration so that, when the synchronous rectifier Q4 drain voltage level rises above the bias voltage level of the high voltage blocking switch Q6 gate, the high voltage blocking switch Q6 will turn off to protect the differential transistor Q5b. The diode D1 clamps any voltage spike that can occur as the high voltage blocking switch Q6 switches off.

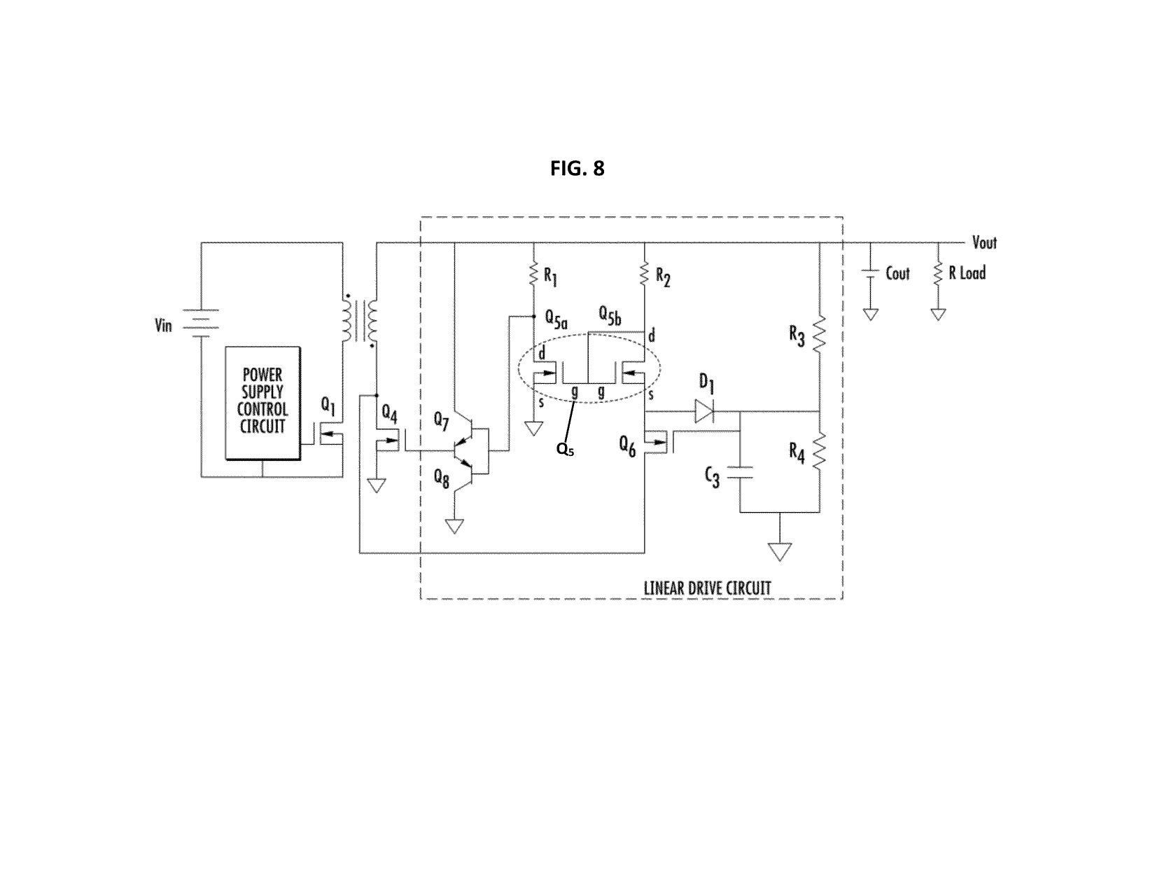

In another application of the drive circuit, the biasing resistors R1 and R2 can be mismatched so as to allow the current through the synchronous rectifier Q4 to reverse direction before the gate drive is removed. An example of this is provided in FIG. 8 that shows a critical conduction mode flyback circuit. By making the resistance of resistor R2 larger than the resistance of resistor R1, an offset in the biasing of the differential transistor pair Q5a and Q5b is created, which requires a positive voltage at the drain of the synchronous rectifier Q4 before the differential transistor Q5a can conduct enough to turn off the synchronous rectifier Q4. By properly controlling this offset, the correct amount of energy required to regenerate the primary winding of the flyback transformer can be stored in the gap of the flyback transformer core. Then, when the synchronous rectifier Q4 switches off, the primary voltage will ring down to zero, allowing for zero voltage switching (ZVS) of the flyback primary transistor Q1. The flyback primary transistor is preferably a MOSFET, for example.

FIG. 8 is a circuit diagram of a power converter including a drive circuit according to a second preferred embodiment of the present application in a typical application of a critical conduction mode flyback converter. Circuit elements in the circuit diagram of FIG. 8 that are the same as the circuit elements in the circuit diagrams of FIGS. 6 and 7 are identified the same reference symbols. The synchronous rectifier Q4 can be used to zero voltage switch the flyback primary switch Q1 if the synchronous rectifier Q4 drive circuit requires reverse current in the synchronous rectifier Q4 before it can be turned off.

As described above, the voltage at the gate of synchronous rectifier Q4 when its drain-to-source voltage Vds is zero can be adjusted up or down by changing the resistance value of the resistor R1. If, for example, the resistance value of the resistor R1 is made to be smaller than the resistance value of the resistor R2, then the synchronous rectifier Q4 gate voltage will be higher when the synchronous rectifier Q4 drain-to-source voltage Vds is zero. If the resulting gate voltage is high enough that synchronous rectifier Q4 is still on when its drain-to-source voltage Vds is zero, then it follows that, for the gate voltage to be low enough to turn off synchronous rectifier Q4, it will require a slightly positive drain-to-source voltage Vds. To get a positive drain-to-source voltage Vds, the current through synchronous rectifier's Q4 source-to-drain must reverse direction and flow from synchronous rectifier's Q4 drain-to-source. This changes the function of the synchronous rectifier Q4 from a diode to a flyback MOSFET, similar to primary switch Q1. This only occurs at the very end of the rectification cycle that is defined as the point in time when the secondary current is zero.

By controlling the amount of mismatch in the biasing resistors R1 and R2, the magnitude of the positive drain-to-source voltage Vds, which corresponds to a low enough gate voltage to turn off the synchronous rectifier Q4, can be set. In turn, the drain-to-source Vds is related to the reverse current (drain-to-source) in synchronous rectifier Q4 by its on resistance, i.e., Ids×Rdson=Vds, where Ids is the reverse current from drain-to-source, Rdson is the drain-to-source on resistance value of the synchronous rectifier Q4, and Vds is the drain-to-source. Therefore, the amount of reverse current in the synchronous rectifier Q4 can be controlled to be approximately equal to the amount of current needed to store sufficient energy in the flyback transformer to fully discharge the parasitic capacitance in the circuit so that the primary switch Q1 will ring down to zero and allow ZVS. The energy stored in the flyback transformer is ½×Lsec×irev², where Lsec is the secondary magnetizing inductance of the flyback transformer and irev is the amount of reverse current needed in the synchronous rectifier Q4 to lower the gate voltage to turn it off. This will happen during each switching cycle, regardless of output load. Also, the energy in the flyback transformer is stored in the gap between the transformer core halves.

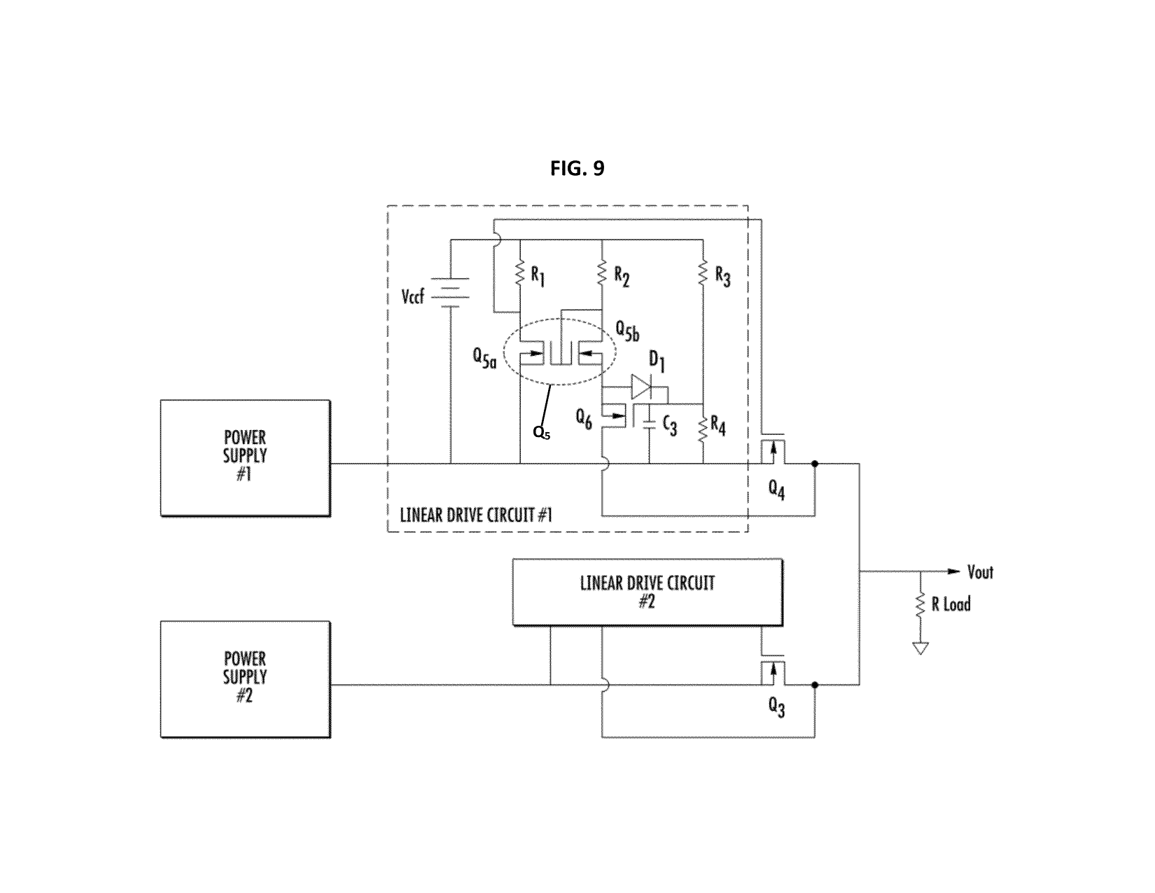

In a third preferred embodiment of the present invention, the synchronous rectifier Q4 is preferably used as an output ORing diode to provide fault isolation and hot swap functionality to multiple power supplies provided in parallel. FIG. 9 is a circuit diagram of a power converter including a drive circuit that includes a synchronous rectifier Q4 that can also be used to perform an ORing diode function for paralleling multiple power supply outputs. Circuit elements in the circuit diagram of FIG. 9 that are the same as the circuit elements in the circuit diagrams of FIGS. 6-8 use the same reference symbols. When power supplies are designed to be installed into a power system that is operating, an output ORing diode or ORing field-effect transistor (FET) is preferably included.

The first purpose of the ORing device, either a diode or FET, is to isolate the output capacitor bank within the power supply to be installed in the operating power system from the live, i.e., powered, bus of the operating power system that the power supply is to be connected to. If the output ORing diode were not present, then the discharged capacitor bank of the new power supply would form a temporary short across the live bus. This short across the live bus would create a large dip in the bus voltage, potentially upsetting the operation of the power system. It would also cause an arc across and corresponding damage to the connector contacts of the power supply being added (the hot-plugged power supply) due to the high currents resulting from the temporary short of the discharged output capacitor bank.

The second purpose of the ORing device is to provide redundant fault isolation. The ORing device prevents a single failure from taking down an entire power system. If a short circuit were to occur in the output section of a single power supply installed in a redundant power supply system, then that short could take down the entire bus of the power system. By including an output ORing device, the short circuit will be limited to that one power supply because the ORing device will block current from flowing into the shorted power supply. The ORing device will only allow current to flow out of each unit, not into a shorted power supply.

Although MOSFETs are preferably shown for the differential transistor pair Q5a and Q5b, bipolar junction transistors could also be used for the differential amplifier stage. While MOSFETs provide higher speed operation and faster turn on of the synchronous rectifier Q4, bipolar transistors typically offer higher transconductance, and thus a higher synchronous rectifier Q4 gate-to-source voltage Vgs for a given synchronous rectifier Q4 drain-to-source voltage Vds, thereby allowing a smaller device to be used for the synchronous rectifier Q4, while having the same drain-to-source voltage Vds voltage drop.

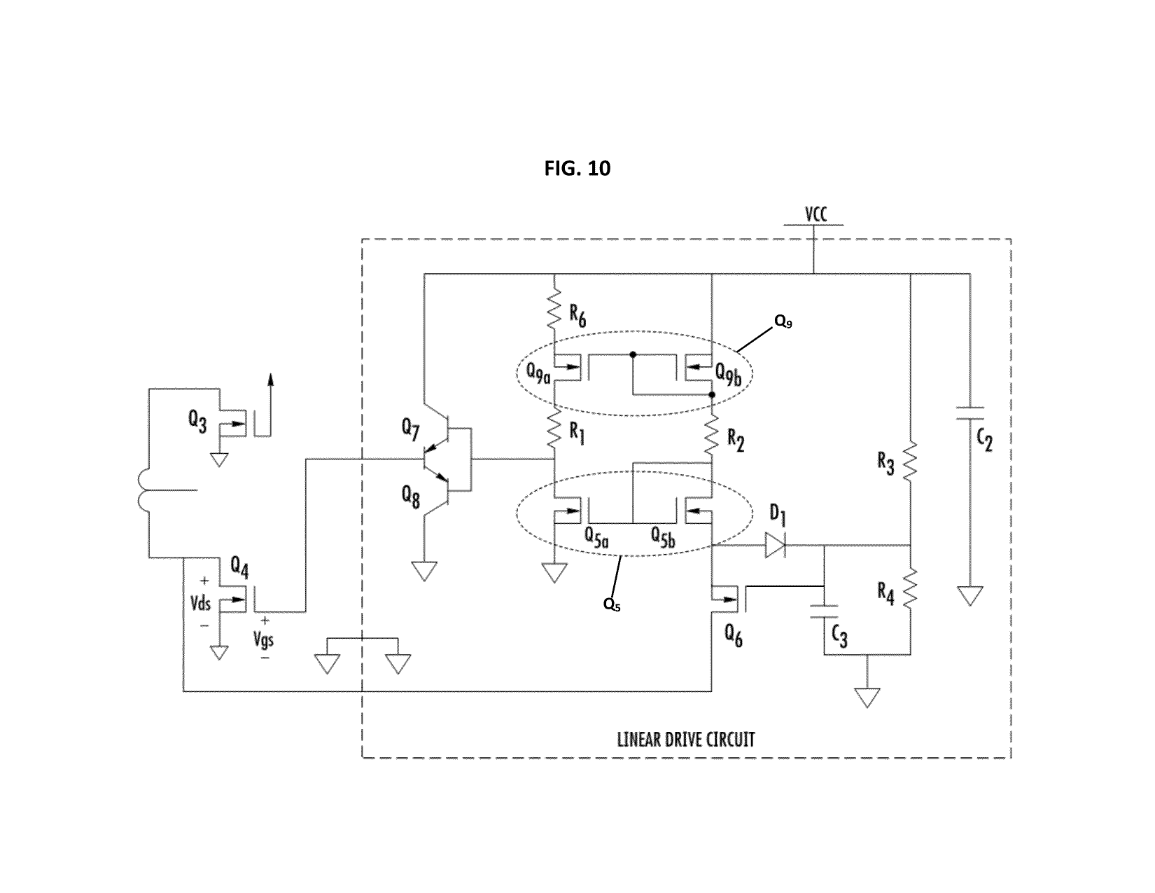

In a fourth preferred embodiment of the present invention, the gain of the differential amplifier stage Q5 can be increased to provide a higher gate drive voltage level than would otherwise be possible with a single differential amplifier stage Q5. FIG. 10 shows a modification of the drive circuit shown in FIG. 7 in which a current mirror Q9 with transistors Q9a and Q9b is preferably added. FIG. 10 is a circuit diagram of a drive circuit according to a fourth preferred embodiment in which a current mirror is added to the drive circuit to increase the gate-to-source voltage Vgs for a given negative drain-to-source voltage Vds, allowing a smaller device to be used for the synchronous rectifier Q4. The current mirror Q9 increases the gain by providing a high impedance pull up to the collector of the differential transistor Q5a, thereby increasing its voltage gain. Resistor R2 sets the bias level of the differential transistor pair Q5a and Q5b, and the resistance ratio of resistor R2/resistor R1 sets the voltage gain of the overall differential amplifier stage Q5. Resistor R6 can be used to trim the synchronous rectifier Q4 gate voltage offset for when there is zero volts on the synchronous rectifier Q4 drain. As with the differential amplifier stage Q5, the current mirror Q9 can also be used with a bipolar transistor.

If a MOSFET is used as the synchronous rectifier, then the drive circuits of the preferred embodiments of the present invention preferably reduce the effects of the synchronous rectifier MOSFET's thermal runaway. Temperature increases in a MOSFET cause the on state resistance Rds to also increase. When a MOSFET is fully enhanced, i.e., when further increases in the gate voltage do not cause further reductions in the on state resistance from the drain to the source Rds, the MOSFET's on state resistance Rds also increases as the MOSFET gets hotter because of the power dissipation in the MOSFET. The increased on state resistance Rds then results in additional power loss, because Ploss=I²R, where Ploss is the power loss, I is the current through the MOSFET channel, and R is the MOSFET's Rds. When the temperature reaches a critical value, the MOSFET's heatsink loses its ability to stabilize the temperature rise with additional power, and the MOSFET's temperature quickly rises to the point of failure.

The drive circuits of the preferred embodiments of the present invention counter this effect provided that the synchronous rectifier MOSFET is not yet fully enhanced. The additional on resistance due to higher device temperature creates a higher voltage drop from source to drain which automatically results in a higher output drive voltage from the differential amplifier circuit. The serves to limit the device temperature rise until the drive level becomes high enough to fully enhance the synchronous rectifier MOSFET.

In addition, if a MOSFET is used as the synchronous rectifier, then the drive circuits of the preferred embodiments of the present invention preferably prevent conduction of the intrinsic body diode in the synchronous rectifier MOSFET as the synchronous rectifier MOSFET is turning off. Although the drive circuits of the preferred embodiments of the present invention will allow some body diode conduction at the beginning of the conduction period due to drive circuit delay; at turn off, the drive signal maintains the channel conduction until the load current reverses direction. Because of the gain characteristics of the differential amplifier stage of the preferred embodiments of the present invention, the voltage drop across the channel of the synchronous rectifier is maintained to be much less than the voltage drop of the body diode so the body diode cannot conduct. This eliminates any power loss associated with the reverse recovery charge of the synchronous rectifier MOSFET. If the body diode is allowed to conduct just prior to device turn off, charge will be stored in the body diode. Then, when the current in the synchronous rectifier MOSFET reverses direction, a substantial amount of reverse charge must be delivered to the body diode during the recovery process before the body diode can be turned off. The delivered charge would then result in additional power loss each time the synchronous rectifier is turned off.

The drive circuits of the preferred embodiments of the present invention preferably automatically prevent reverse operation of the synchronous rectifier. Certain modes of operation in some conventional control techniques in which the on/off control of the synchronous rectifier is synchronized to the on/off control of the primary switches can inadvertently operate in reverse, supplying power from the output to the input rather than the other way around. One example is when two power supplies are connected in parallel without a true ORing device. It is possible for one power supply with a slightly higher voltage regulation set point to feed current into the other power supply. If the synchronous rectifiers are simply driven from a time delayed version of the primary switch gate signal, then the power supply with the lower set point will try to reduce the output voltage. This can result in power flowing from the output to the input. This can cause an overvoltage to occur on the primary voltage rail, and hard recovery of the body diodes in the primary switches. Either way, the power supply can be damaged by such reverse operation. Similar problems can occur from load steps from a heavy to a light load condition. In this case, the output capacitance of the power supply can be discharged into the input. This can also damage the primary switches due to hard recovery of the body diodes. Because the balanced form of the drive circuit of the preferred embodiments of the present invention automatically switches the synchronous rectifiers off before the current can reverse direction, these problems are averted.

The drive circuit of the preferred embodiments of the present invention is applicable to any other application where a MOSFET or other similar transistor is used as a diode to reduce the forward voltage drop of the diode.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. A drive circuit arranged to drive a synchronous rectifier of a power converter comprising:
a differential amplifier stage connected to the synchronous rectifier and arranged to supply a drive signal to the synchronous rectifier to turn the synchronous rectifier on and off; and
a high voltage blocking stage connected between the synchronous rectifier and the differential amplifier stage; wherein
the differential amplifier stage is arranged such that a voltage level of the drive signal depends on a load of the power converter.

2. A drive circuit according to claim 1, wherein:
the differential amplifier stage includes first and second transistors;
the first transistor is arranged to be connected to the synchronous rectifier to supply the drive signal;
the second transistor is arranged to receive a signal corresponding to the load of the power converter; and
the first and second transistors are arranged such that the voltage level of the drive signal depends on a transconductance of the first transistor and a drain-to-source voltage of the synchronous rectifier.

3. A drive circuit according to claim 2, further comprising:
a first resistor connected to the first transistor; and
a second resistor connected to the second transistor.

4. A drive circuit according to claim 3, wherein the voltage level of the drive signal depends on a resistance of the first resistor.

5. A drive circuit according to claim 3, wherein a resistance of the first resistor is the same as a resistance of the second resistor.

6. A drive circuit according to claim 2, wherein the first and second transistors are included in a single package.

7. A drive circuit according to claim 1, further comprising a buffer circuit connected between the differential amplifier stage and the synchronous rectifier.

8. A drive circuit according to claim 1, wherein the voltage level of the drive signal is automatically reduced when the load is reduced.

9. A drive circuit according to claim 1, wherein the differential amplifier stage is a linear differential amplifier stage.

10. A drive circuit according to claim 1, wherein the synchronous rectifier is a MOSFET.

11. A drive circuit according to claim 2, wherein the first and second transistors are MOSFETs or bipolar transistors.

12. A driver circuit according to claim 1, further comprising a current mirror arranged to increase a gain of the drive circuit.

13. A power converter comprising:
a transformer including primary and secondary windings;
a synchronous rectifier connected to the secondary winding; and
a drive circuit according to claim 1 connected to the synchronous rectifier to drive the synchronous rectifier.

14. A power converter according to claim 13, further comprising:
a primary switch connected to the primary winding; and
a control circuit connected to the primary switch; wherein the drive circuit is not connected to the control circuit.

15. A power converter according to claim 13, further comprising an output filter stage.

16. A power converter according to claim 13, wherein the power converter is a critical conduction mode flyback power converter.

17. A power converter according to claim 14, wherein the control circuit is arranged to provide zero voltage switching of the primary switch.

18. A power converter comprising:
first and second synchronous rectifiers;
first and second drive circuits according to claim 1 connected to the first and second synchronous rectifiers, respectively, to drive the first and second synchronous rectifiers.

19. A power converter according to claim 18, further comprising a transformer including primary and secondary windings; wherein
the first and second synchronous rectifiers are connected to the secondary winding.

20. A power converter system comprising:
first and second power supplies connected to provide a single output; wherein
each of the first and second power supplies includes:
an ORing transistor arranged to act as a diode; and
a drive circuit arranged to drive the ORing transistor including a differential amplifier stage connected to the ORing transistor and arranged to supply a drive signal to the ORing transistor to turn the ORing transistor on and off; wherein
the differential amplifier stage is arranged such that a voltage level of the drive signal depends on a load of a corresponding one of the first and second power supplies.
